(19) United States
(12) Patent Application Publication
(10) Pub. No.: US 2025/0379195 A1
(43) Pub. Date: Dec. 11, 2025

(54) INTEGRATED INDUCTORS USING MULTIPLE DIES

(71) Applicant: Micron Technology, Inc., Boise, ID (US)

(72) Inventors: Kaveri Jain, Hyderabad (IN); Srivatsan Venkatesan, Gopanpalle (IN); Sushma Dogiparthi, Hyderabad (IN); Salil Shashikant Mujumdar, Nanakaramguda (IN); Saurabh Raj, Hyderabad (IN); Telajala Venkata Mahendra, Hyderabad (IN); Rajat Vishnoi, Bangalore (IN)

(21) Appl. No.: 19/214,798

(22) Filed: May 21, 2025

Related U.S. Application Data
(60) Provisional application No. 63/657,526, filed on Jun. 7, 2024.

(51) Int. Cl. H01L 25/16; H01L 23/00; H01L 23/522; H01L 23/528; H10B 80/00; H10D 80/20; H10D 80/30

(52) U.S. Cl. CPC H01L 25/16; H01L 23/5227; H01L 23/528; H01L 23/5283; H10B 80/00; H10D 80/211; H10D 80/30; H01L 24/08; H01L 24/80; H01L 2224/08145; H01L 2224/80895; H01L 2224/80896; H01L 2924/1431; H01L 2924/1438; H01L 2924/19042

(57) ABSTRACT

A memory device can include an array of memory cells and an integrated inductor. The array can be provided on a first semiconductor substrate. First conductive portions of the inductor can be provided on the first semiconductor substrate, and each of the first conductive portions provides less than one revolution of a conductive path of the inductor. Second conductive portions of the inductor can be vertically separate from the first conductive portions and coupled to the first conductive portions to provide multiple revolutions of the conductive path of the inductor. The second conductive portions of the inductor can be provided on a different second semiconductor substrate. The inductor can optionally include a core region that is filled with a magnetic or non-magnetic material.

### PRIORITY APPLICATION

This application claims the benefit of priority to U.S. Provisional Application Ser. No. 63/657,526, filed Jun. 7, 2024, which is incorporated herein by reference in its entirety.

### BACKGROUND

Inductors play an important role in power circuits, but are largely absent from on-chip integration. Power circuits, such as DC boost converters, DC buck converters, charge recyclers, or t-coils, among others, use inductors to store energy and solve complex engineering problems. Conventional inductors can be relatively expensive to manufacture due to material constraints.

In NAND arrays, integrated charge pumps are conventionally used to generate high voltages. Such charge pumps can be physically large, occupying a relatively large amount of on-chip area, and can have poor conversion efficiency.

### BRIEF DESCRIPTION OF THE SEVERAL VIEWS OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

To easily identify the discussion of any particular element or act, the most significant digit or digits in a reference number refer to the figure number in which that element is first introduced.

FIG. 1 illustrates an environment including a memory device, according to some examples.

FIG. 2 illustrates schematic diagrams of an example of a 3D NAND architecture semiconductor memory array, according to some examples.

FIG. 3 illustrates schematic diagrams of an example of a 3D NAND architecture semiconductor memory array, according to some examples.

FIG. 4 illustrates a block diagram of a memory device, according to some examples.

FIG. 5 illustrates generally an example of an integrated inductor that can comprise a bonded assembly of multiple dies or wafers.

FIG. 6 illustrates generally an example of a vertical cross-section of a first portion of a first memory device that comprises an integrated inductor and multiple dies.

FIG. 7 illustrates generally an example of a vertical cross-section of a second portion of the first memory device that comprises an integrated inductor and multiple dies.

FIG. 8 illustrates generally an example of a vertical cross-section of a memory device with an integrated inductor and an inductor core.

FIG. 9 illustrates generally an example of a vertical cross-section of a first portion of a second memory device that comprises an integrated inductor and multiple dies.

FIG. 10 illustrates generally an example of a vertical cross-section of a second portion of the second memory device that comprises an integrated inductor and multiple dies.

FIG. 11 illustrates an example of a method that includes forming an inductor using conductors in multiple wafers or dies that are bonded together.

### DETAILED DESCRIPTION

Challenges to implementing an on-chip inductor can include achieving a useful inductance density and q-factor. For example, desirable characteristics of an on-chip inductor include an inductance density on the order of 100 nH/mm² or more, and a q-factor greater than about 20. In an example, a useful on-chip inductor can have a low internal resistance to achieve a high q-factor, for example, less than 100 ohms.

In various examples, an on-chip inductor can be formed using structures that are similar to structures used to implement memory, such as NAND memory or 3D DRAM. NAND flash memory, for example, uses pillar-like contact structures, with a relatively large vertical height relative to width of each pillar. A solenoid inductor, such as comprising multiple conductive coils connected in series to provide a spring-like structure, can be formed using, for example, pillars with one or more modifications. The solenoid inductor using memory device structures can have high inductance density and q-factor. According to some examples, conventional charge pumps to supply high voltages to memory arrays are replaced by a boost converter that uses the on-chip solenoid inductor.

The term “solenoid” is used herein and should be recognized by one of ordinary skill in the art to represent helical and helical-like electromagnets. An example of a solenoid is an electromechanically inductive wire, such as can be wound around an armature, to form a round coil. Should the same wire be wound into a coil with right angles forming a rectangular cross-section, or wound into a coil with a non-rectangular and non-circular cross-section, the resultant electromagnet can nevertheless be considered a solenoid.

The following detailed description refers to the accompanying drawings that show, by way of illustration, various examples that can be implemented. These examples are described in sufficient detail to enable those of ordinary skill in the art to practice these and other examples. Other examples can be used, and structural, logical, mechanical, and electrical changes can be made to these examples. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical and/or horizontal component to the direction of their structure. The various examples are not necessarily mutually exclusive, as some examples can be combined with one or more other examples to form new examples. The following detailed description is, therefore, not to be taken in a limiting sense.

Memory devices can be provided as semiconductor-based integrated circuits in computers or other electronic devices. There are many different types of memory devices, including volatile and non-volatile memory.

Volatile memory requires power to maintain its data, and includes random-access memory (RAM), dynamic random-access memory (DRAM), or synchronous dynamic random-access memory (SDRAM), among others.

Non-volatile memory can retain stored data when not powered, and includes flash memory, read-only memory (ROM), electrically erasable programmable ROM (EEPROM), static RAM (SRAM), erasable programmable ROM (EPROM), resistance variable memory, such as phase-change random-access memory (PCRAM), resistive random-access memory (RRAM), magnetoresistive random-access memory (MRAM), or 3D XPoint™ memory, among others.

Flash memory is used as non-volatile memory for a wide range of electronic applications. Flash memory devices typically include one or more groups of one-transistor, floating gate or charge trap memory cells that allow for high memory densities, high reliability, and low power consumption.

Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are coupled to an access line (e.g., a word line). In a NOR architecture, the drains of each memory cell in a column of the array are coupled to a data line (e.g., a bit line). In a NAND architecture, the drains of each memory cell in a string of the array are coupled together in series, source to drain, between a source line and a bit line.

Both NOR and NAND architecture semiconductor memory arrays are accessed through decoders that activate specific memory cells by selecting the word line coupled to their gates. In a NOR architecture semiconductor memory array, once activated, the selected memory cells place their data values on bit lines, causing different currents to flow depending on the state at which a particular cell is programmed. In a NAND architecture semiconductor memory array, a high bias voltage is applied to a drain-side select gate (SGD) line. Word lines coupled to the gates of the unselected memory cells of each group are driven at a specified pass voltage (e.g., Vpass) to operate the unselected memory cells of each group as pass transistors (e.g., to pass current in a manner unrestricted by their stored data values). Current then flows from the source line to the bit line through each series coupled group, restricted only by the selected memory cells of each group, placing current encoded data values of selected memory cells on the bit lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data.

However, flash memory cells can also represent one of more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs).

Traditional memory arrays are two-dimensional (2D) structures arranged on a surface of a semiconductor substrate. To increase memory capacity for a given area, and to decrease cost, the size of the individual memory cells has decreased. However, there is a technological limit to the reduction in size of the individual memory cells, and thus, to the memory density of 2D memory arrays. In response, three-dimensional (3D) memory structures, such as 3D NAND architecture semiconductor memory devices, are being developed to further increase memory density and lower memory cost.

Such 3D NAND devices often include strings of storage cells, coupled in series (e.g., drain to source), between one or more source-side select gates (SGSs) proximate a source, and one or more drain-side select gates (SGDs) proximate a bit line. In an example, the SGSs or the SGDs can include one or more field-effect transistors (FETs) or metal-oxide semiconductor (MOS) structure devices, etc. In some examples, the strings will extend vertically, through multiple vertically spaced tiers containing respective word lines. A semiconductor structure (e.g., a polysilicon structure) may extend adjacent to a string of storage cells to form a channel for the storages cells of the string. In the example of a vertical string, the polysilicon structure may be in the form of a vertically extending pillar. In some examples the string may be “folded,” and thus arranged relative to a U-shaped pillar. In other examples, multiple vertical structures may be stacked to form stacked arrays of storage cell strings.

Memory arrays or devices can be combined together to form a storage volume of a memory system, such as a solid-state drive (SSD), a Universal Flash Storage (UFS™) device, a MultiMediaCard (MMC) solid-state storage device, an embedded MMC device (eMMC™), etc. An SSD can be used as, among other things, the main storage device of a computer, having advantages over traditional hard drives with moving parts with respect to, for example, performance, size, weight, ruggedness, operating temperature range, and power consumption. For example, SSDs can have reduced seek time, latency, or other delay associated with magnetic disk drives (e.g., electromechanical, etc.). SSDs use non-volatile memory cells, such as flash memory cells to obviate internal battery supply requirements, thus allowing the drive to be more versatile and compact.

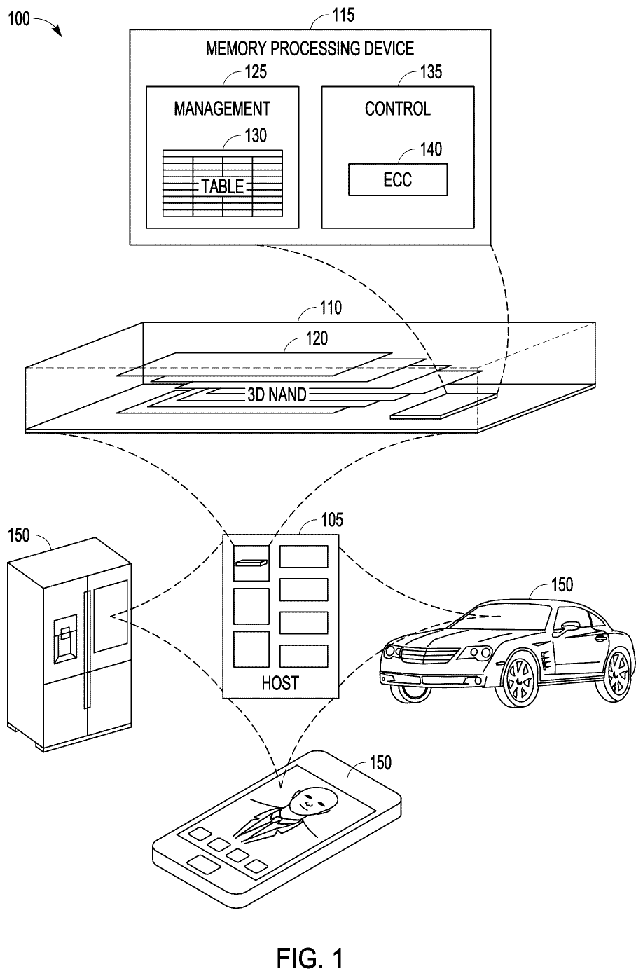

FIG. 1 illustrates an example of an environment 100 including a host device 105 and a memory device 110 configured to communicate over a communication interface. The host device 105 or the memory device 110 may be included in a variety of products 150, such as Internet of Things (IoT) devices (e.g., a refrigerator or other appliance, sensor, motor or actuator, mobile communication device, automobile, drone, etc.) to support processing, communications, or control of the product 150.

The memory device 110 includes a memory controller 115 and a memory array 120 including, for example, a number of individual memory die (e.g., three-dimensional (3D) NAND die). In 3D architecture semiconductor memory technology, vertical structures are stacked, increasing the number of tiers, physical pages, and accordingly, the density of a memory device (e.g., a storage device). In an example, the memory device 110 can be a discrete memory or storage device component of the host device 105. In other examples, the memory device 110 can be a portion of an integrated circuit (e.g., system on a chip (SOC), etc.), stacked or otherwise included with one or more other components of the host device 105.

One or more communication interfaces can be used to transfer data between the memory device 110 and one or more other components of the host device 105, such as a Serial Advanced Technology Attachment (SATA) interface, a Peripheral Component Interconnect Express (PCIe) interface, a Universal Serial Bus (USB) interface, a Universal Flash Storage (UFS) interface, an eMMC™ interface, or one or more other connectors or interfaces. The host device 105 can include a host system, an electronic device, a processor, a memory card reader, or one or more other electronic devices external to the memory device 110. In some examples, the host device 105 may be a machine having some portion, or all, of the components discussed in reference to the machine 1700 of 17.

The memory controller 115 can receive instructions from the host device 105, and can communicate with the memory array, such as to transfer data to (e.g., write or erase) or from (e.g., read) one or more of the memory cells, planes, sub-blocks, blocks, or pages of the memory array. The memory controller 115 can include, among other things, circuitry or firmware, including one or more components or integrated circuits. For example, the memory controller 115 can include one or more memory control units, circuits, or components configured to control access across the memory array 120 and to provide a translation layer between the host device 105 and the memory device 110. The memory controller 115 can include one or more input/output (I/O) circuits, lines, or interfaces to transfer data to or from the memory array 120. The memory controller 115 can include a memory manager 125 and an array controller 135.

The memory manager 125 can include, among other things, circuitry or firmware, such as a number of components or integrated circuits associated with various memory management functions. For purposes of the present description example memory operation and management functions will be described in the context of NAND memory. Persons skilled in the art will recognize that other forms of non-volatile memory may have analogous memory operations or management functions. Such NAND management functions include wear leveling (e.g., garbage collection or reclamation), error detection or correction, block retirement, or one or more other memory management functions. The memory manager 125 can parse or format host commands (e.g., commands received from a host) into device commands (e.g., commands associated with operation of a memory array, etc.), or generate device commands (e.g., to accomplish various memory management functions) for the array controller 135 or one or more other components of the memory device 110.

The memory manager 125 can include a set of management tables 130 configured to maintain various information associated with one or more component of the memory device 110 (e.g., various information associated with a memory array or one or more memory cells coupled to the memory controller 115). For example, the management tables 130 can include information regarding block age, block erase count, error history, or one or more error counts (e.g., a write operation error count, a read bit error count, a read operation error count, an erase error count, etc.) for one or more blocks of memory cells coupled to the memory controller 115. In certain examples, if the number of detected errors for one or more of the error counts is above a threshold, the bit error can be referred to as an uncorrectable bit error. The management tables 130 can maintain a count of correctable or uncorrectable bit errors, among other things.

The array controller 135 can include, among other things, circuitry or components configured to control memory operations associated with writing data to, reading data from, or erasing one or more memory cells of the memory device 110 coupled to the memory controller 115. The memory operations can be based on, for example, host commands received from the host device 105, or internally generated by the memory manager 125 (e.g., in association with wear leveling, error detection or correction, etc.).

The array controller 135 can include an error correction code (ECC) component 140, which can include, among other things, an ECC engine or other circuitry configured to detect or correct errors associated with writing data to or reading data from one or more memory cells of the memory device 110 coupled to the memory controller 115. The memory controller 115 can be configured to actively detect and recover from error occurrences (e.g., bit errors, operation errors, etc.) associated with various operations or storage of data, while maintaining integrity of the data transferred between the host device 105 and the memory device 110, or maintaining integrity of stored data (e.g., using redundant RAID storage, etc.), and can remove (e.g., retire) failing memory resources (e.g., memory cells, memory arrays, pages, blocks, etc.) to prevent future errors.

In some examples, the memory array may comprise a number of NAND dies and one or more functions of the memory controller 115 for a particular NAND die may be implemented on an on-die controller on that particular die. Other organizations and delineations of control functionality may also be utilized, such as a controller for each die, plane, superblock, block, page, and the like.

The memory array 120 can include several memory cells arranged in, for example, a number of devices, semiconductor dies, planes, sub-blocks, blocks, or pages. In operation, data is typically written to or read from the NAND memory device 110 in pages, and erased in blocks. However, one or more memory operations (e.g., read, write, erase, etc.) can be performed on larger or smaller groups of memory cells, as desired. The data transfer size of a NAND memory device 110 is typically referred to as a page, whereas the data transfer size of a host is typically referred to as a sector.

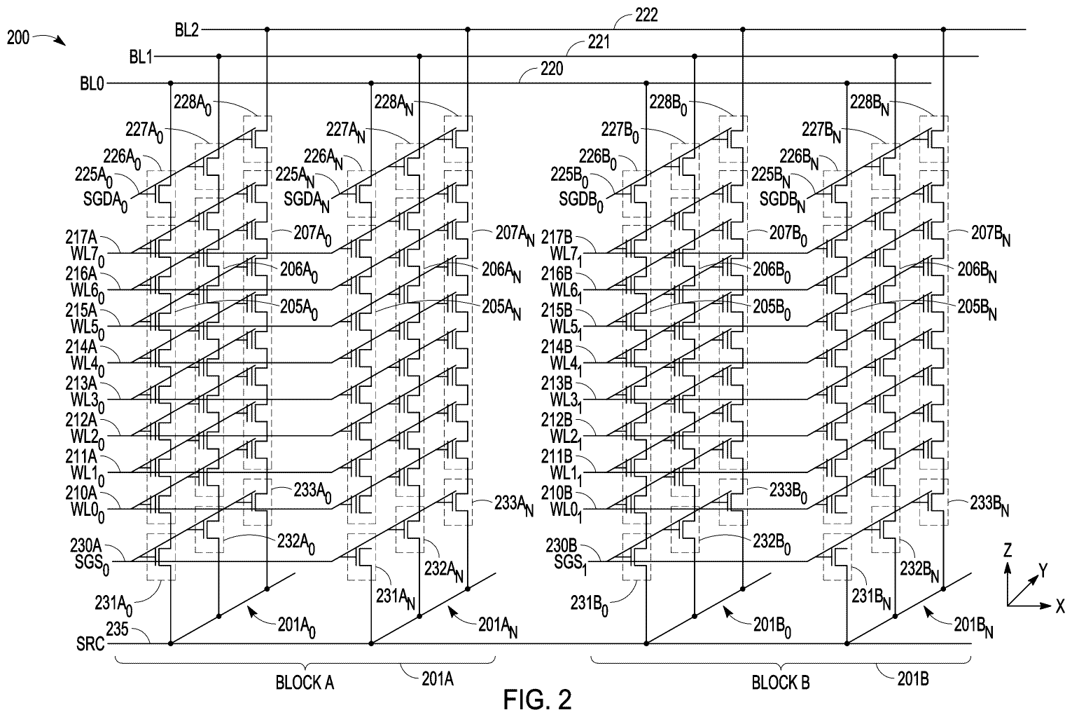

FIG. 2 illustrates an example schematic diagram of a 3D NAND architecture semiconductor memory array 200 including a number of strings of memory cells (e.g., first-third A₀ memory strings 205A₀-207A₀, first-third Aₙ memory strings 205Aₙ-207Aₙ, first-third B₀ memory strings 205B₀-207B₀, first-third Bₙ memory strings 205Bₙ-207Bₙ, etc.), organized in blocks (e.g., block A 201A, block B 201B, etc.) and sub-blocks (e.g., sub-block A₀ 201A₀, sub-block Aₙ 201Aₙ, sub-block B₀ 201B₀, sub-block Bₙ 201Bₙ, etc.). The memory array 200 represents a portion of a greater number of similar structures that would typically be found in a block, device, or other unit of a memory device.

Each string of memory cells includes a number of tiers of charge storage transistors (e.g., floating gate transistors, charge-trapping structures, etc.) stacked in the Z direction, source to drain, between a source line (SRC) 235 or a source-side select gate (SGS) (e.g., first-third A₀ SGS 231A₀-233A₀, first-third Aₙ SGS 231Aₙ-233Aₙ, first-third B₀ SGS 231B₀-233B₀, first-third Bₙ SGS 231Bₙ-233Bₙ, etc.) and a drain-side select gate (SGD) (e.g., first-third A₀ SGD 226A₀-228A₀, first-third Aₙ SGD 226Aₙ-228Aₙ, first-third B₀ SGD 226B₀-228B₀, first-third Bₙ SGD 226Bₙ-228Bₙ, etc.). Each string of memory cells in the 3D memory array can be arranged along the X direction as data lines (e.g., bit lines (BL) BL0-BL2 220-222), and along the Y direction as physical pages.

Within a physical page, each tier represents a row of memory cells, and each string of memory cells represents a column. A sub-block can include one or more physical pages. A block can include a number of sub-blocks (or physical pages) (e.g., 128, 256, 384, etc.). Although illustrated herein as having two blocks, each block having two sub-blocks, each sub-block having a single physical page, each physical page having three strings of memory cells, and each string having 8 tiers of memory cells, in other examples, the memory array 200 can include more or fewer blocks, sub-blocks, physical pages, strings of memory cells, memory cells, or tiers. For example, each string of memory cells can include more or fewer tiers (e.g., 16, 32, 64, 128, etc.), as well as one or more additional tiers of semiconductor material above or below the charge storage transistors (e.g., select gates, data lines, etc.), as desired. As an example, a 48 GB TLC NAND memory device can include 18,592 bytes (B) of data per page (16,384+2208 bytes), 1536 pages per block, 548 blocks per plane, and 4 or more planes per device.

Each memory cell in the memory array 200 includes a control gate (CG) coupled to (e.g., electrically or otherwise operatively connected to) an access line (e.g., word lines (WL) WL0₀-WL7₀ 210A-217A, WL0₁-WL7₁ 210B-217B, etc.), which collectively couples the control gates (CGs) across a specific tier, or a portion of a tier, as desired. Specific tiers in the 3D memory array, and accordingly, specific memory cells in a string, can be accessed or controlled using respective access lines. Groups of select gates can be accessed using various select lines. For example, first-third A₀ SGD 226A₀-228A₀ can be accessed using an A₀ SGD line SGDA₀ 225A₀, first-third Aₙ SGD 226Aₙ-228Aₙ can be accessed using an Aₙ SGD line SGDAₙ 225Aₙ, first-third B₀ SGD 226B₀-228B₀ can be accessed using an B₀ SGD line SGDB₀ 225B₀, and first-third Bₙ SGD 226Bₙ-228Bₙ can be accessed using an Bₙ SGD line SGDBₙ 225Bₙ. First-third A₀ SGS 231A₀-233A₀ and first-third Aₙ SGS 231Aₙ-233Aₙ can be accessed using a gate select line SGS₀ 230A, and first-third B₀ SGS 231B₀-233B₀ and first-third Bₙ SGS 231Bₙ-233Bₙ can be accessed using a gate select line SGS₁ 230B.

In an example, the memory array 200 can include a number of tiers of semiconductor material (e.g., polysilicon, etc.) configured to couple the control gates (CGs) of each memory cell or select gate (or a portion of the CGs or select gates) of a respective tier of the array. Specific strings of memory cells in the array can be accessed, selected, or controlled using a combination of bit lines (BLs) and select gates, etc., and specific memory cells at one or more tiers in the specific strings can be accessed, selected, or controlled using one or more access lines (e.g., word lines).

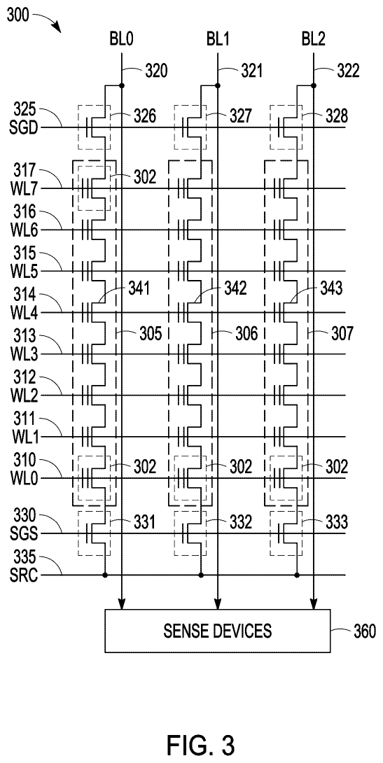

FIG. 3 illustrates an example schematic diagram of a portion of a NAND architecture semiconductor memory array 300 including a plurality of memory cells 302 arranged in a two-dimensional array of strings (e.g., first-third strings 305-307) and tiers (e.g., illustrated as respective word lines (WL) WL0-WL7 310-317, a drain-side select gate (SGD) line 325, a source-side select gate (SGS) line 330, etc.), and sense amplifiers 360. For example, the memory array 300 can illustrate an example schematic diagram of a portion of one physical page of memory cells of a 3D NAND architecture semiconductor memory device, such as illustrated in FIG. 2.

Each string of memory cells is coupled to a source line (SRC) using a respective source-side select gate (SGS) (e.g., first-third SGS 331-333), and to a respective data line (e.g., first-third bit lines (BL) BL0-BL2 320-322) using a respective drain-side select gate (SGD) (e.g., first-third SGD 326-328). Although illustrated with 8 tiers (e.g., using word lines (WL) WL0-WL7 310-317) and three data lines (BL0-BL2 326-328) in the example of FIG. 3, other examples can include strings of memory cells having more or fewer tiers or data lines, as desired.

In a NAND architecture semiconductor memory array, such as the example memory array 300, the state of a selected memory cell 302 can be accessed by sensing a current or voltage variation associated with a particular data line containing the selected memory cell. The memory array 300 can be accessed (e.g., by a control circuit, one or more processors, digital logic, etc.) using one or more drivers. In an example, one or more drivers can activate a specific memory cell, or set of memory cells, by driving a particular potential to one or more data lines (e.g., bit lines BL0-BL2), access lines (e.g., word lines WL0-WL7), or select gates, depending on the type of operation desired to be performed on the specific memory cell or set of memory cells.

To program or write data to a memory cell, a programming voltage (Vpgm) (e.g., one or more programming pulses, etc.) can be applied to selected word lines (e.g., WL4), and thus, to a control gate of each memory cell coupled to the selected word lines (e.g., first-third control gates (CGs) 341-343 of the memory cells coupled to WL4). Programming pulses can begin, for example, at or near 15 V, and, in certain examples, can increase in magnitude during each programming pulse application. While the program voltage is applied to the selected word lines, a potential, such as a ground potential (e.g., Vss), can be applied to the data lines (e.g., bit lines) and substrates (and thus the channels, between the sources and drains) of the memory cells targeted for programming, resulting in a charge transfer (e.g., direct injection or Fowler-Nordheim (FN) tunneling, etc.) from the channels to the floating gates of the targeted memory cells.

In contrast, a pass voltage (Vpass) can be applied to one or more word lines having memory cells that are not targeted for programming, or an inhibit voltage (e.g., Vcc) can be applied to data lines (e.g., bit lines) having memory cells that are not targeted for programming, for example, to inhibit charge from being transferred from the channels to the floating gates of such non-targeted memory cells. The pass voltage can be variable, depending, for example, on the proximity of the applied pass voltages to a word line targeted for programming. The inhibit voltage can include a supply voltage (Vcc), such as a voltage from an external source or supply (e.g., a battery, an AC-to-DC converter, etc.), relative to a ground potential (e.g., Vss).

As an example, if a programming voltage (e.g., 15 V or more) is applied to a specific word line, such as WL4, a pass voltage of 10 V can be applied to one or more other word lines, such as WL3, WL5, etc., to inhibit programming of non-targeted memory cells, or to retain the values stored on such memory cells not targeted for programming. As the distance between an applied program voltage and the non-targeted memory cells increases, the pass voltage required to refrain from programming the non-targeted memory cells can decrease. For example, where a programming voltage of 15 V is applied to WL4, a pass voltage of 10 V can be applied to WL3 and WL5, a pass voltage of 8 V can be applied to WL2 and WL6, a pass voltage of 7 V can be applied to WL1 and WL7, etc. In other examples, the pass voltages, or number of word lines, etc., can be higher or lower, or more or less.

The sense amplifiers 360, coupled to one or more of the data lines (e.g., first, second, or third bit lines (BL0-BL2) 320-322), can detect the state of each memory cell in respective data lines by sensing a voltage or current on a particular data line.

Between applications of one or more programming pulses (e.g., Vpgm), a verify operation can be performed to determine if a selected memory cell has reached its intended programmed state. If the selected memory cell has reached its intended programmed state, it can be inhibited from further programming. If the selected memory cell has not reached its intended programmed state, additional programming pulses can be applied. If the selected memory cell has not reached its intended programmed state after a particular number of programming pulses (e.g., a maximum number), the selected memory cell, or a string, block, or page associated with such selected memory cell, can be marked as defective.

To erase a memory cell or a group of memory cells (e.g., erasure is typically performed in blocks or sub-blocks), an erasure voltage (Vers) (e.g., typically Vpgm) can be applied to the substrates (and thus the channels, between the sources and drains) of the memory cells targeted for erasure (e.g., using one or more bit lines, select gates, etc.), while the word lines of the targeted memory cells are kept at a potential, such as a ground potential (e.g., Vss), resulting in a charge transfer (e.g., direct injection or Fowler-Nordheim (FN) tunneling, etc.) from the floating gates of the targeted memory cells to the channels.

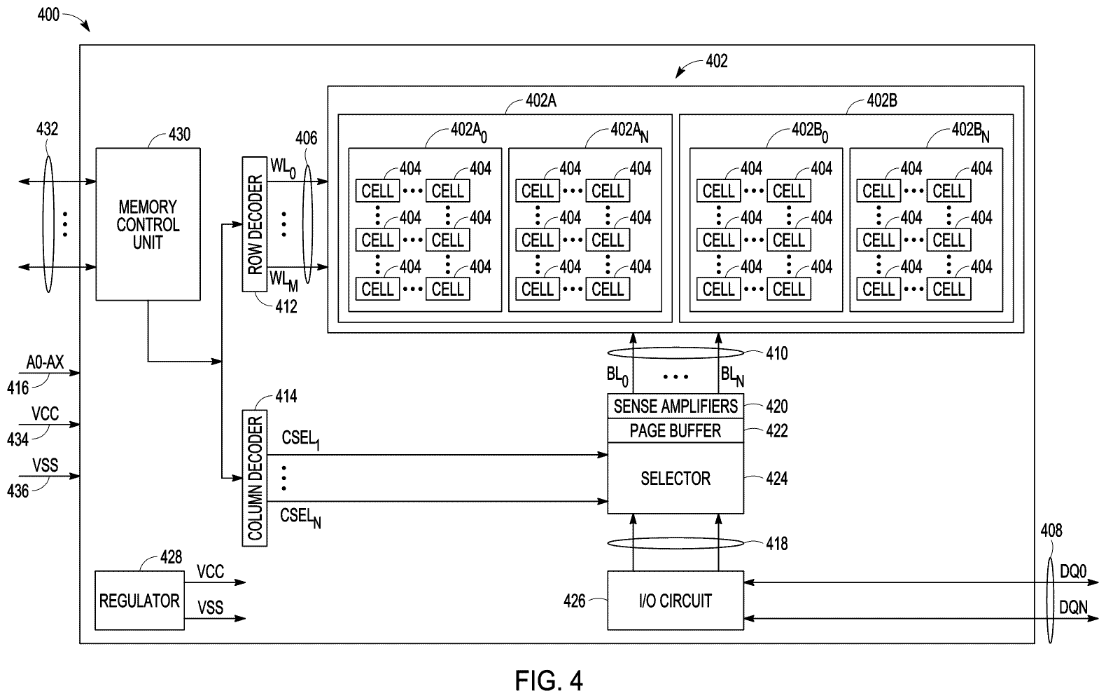

FIG. 4 illustrates an example block diagram of a memory device 400 including a memory array 402 having a plurality of memory cells 404, and one or more circuits or components to provide communication with, or perform one or more memory operations on, the memory array 402. The memory device 400 can include a row decoder 412, a column decoder 414, sense amplifiers 420, a page buffer 422, a selector 424, an input/output (I/O) circuit 426, and a memory control unit 430.

The memory cells 404 of the memory array 402 can be arranged in blocks, such as first and second blocks 402A, 402B. Each block can include sub-blocks. For example, the first block 402A can include first and second sub-blocks 402A₀, 402Aₙ, and the second block 402B can include first and second sub-blocks 402B₀, 402Bₙ. Each sub-block can include a number of physical pages, each page including a number of memory cells 404. Although illustrated herein as having two blocks, each block having two sub-blocks, and each sub-block having a number of memory cells 404, in other examples, the memory array 402 can include more or fewer blocks, sub-blocks, memory cells, etc. In other examples, the memory cells 404 can be arranged in a number of rows, columns, pages, sub-blocks, blocks, etc., and accessed using, for example, access lines 406, first data lines 410, or one or more select gates, source lines, etc.

The memory control unit 430 can control memory operations of the memory device 400 according to one or more signals or instructions received on control lines 432, including, for example, one or more clock signals or control signals that indicate a desired operation (e.g., write, read, erase, etc.), or address signals (A0-AX) received on one or more address lines 416. One or more devices external to the memory device 400 can control the values of the control signals on the control lines 432, or the address signals on the address line 416. Examples of devices external to the memory device 400 can include, but are not limited to, a host, a memory controller, a processor, or one or more circuits or components not illustrated in FIG. 4.

The memory device 400 can use access lines 406 and first data lines 410 to transfer data to (e.g., write or erase) or from (e.g., read) one or more of the memory cells 404. The row decoder 412 and the column decoder 414 can receive and decode the address signals (A0-AX) from the address line 416, can determine which of the memory cells 404 are to be accessed, and can provide signals to one or more of the access lines 406 (e.g., one or more of a plurality of word lines (WL0-WLm)) or the first data lines 410 (e.g., one or more of a plurality of bit lines (BL0-BLn)), such as described above.

The memory device 400 can include sense circuitry, such as the sense amplifiers 420, configured to determine the values of data on (e.g., read), or to determine the values of data to be written to, the memory cells 404 using the first data lines 410. For example, in a selected string of memory cells 404, one or more of the sense amplifiers 420 can read a logic level in the selected memory cell 404 in response to a read current flowing in the memory array 402 through the selected string to the data lines 410.

One or more devices external to the memory device 400 can communicate with the memory device 400 using the I/O lines (DQ0-DQN) 408, address lines 416 (A0-AX), or control lines 432. The input/output (I/O) circuit 426 can transfer values of data in or out of the memory device 400, such as in or out of the page buffer 422 or the memory array 402, using the I/O lines 408, according to, for example, the control lines 432 and address lines 416. The page buffer 422 can store data received from the one or more devices external to the memory device 400 before the data is programmed into relevant portions of the memory array 402, or can store data read from the memory array 402 before the data is transmitted to the one or more devices external to the memory device 400.

The column decoder 414 can receive and decode address signals (A0-AX) into one or more column select signals (CSEL1-CSELn). The selector 424 (e.g., a select circuit) can receive the column select signals (CSEL1-CSELn) and select data in the page buffer 422 representing values of data to be read from or to be programmed into memory cells 404. Selected data can be transferred between the page buffer 422 and the I/O circuit 426 using second data lines 418.

The memory control unit 430 can receive positive and negative supply signals, such as a supply voltage (Vcc) 434 and a negative supply (Vss) 436 (e.g., a ground potential), from an external source or supply (e.g., an internal or external battery, an AC-to-DC converter, etc.). In certain examples, the memory control unit 430 can include a regulator 428 to internally provide positive or negative supply signals.

In an example, a memory device can include non-volatile memory and/or volatile memory components. A non-volatile memory component can include, for example, a negative-and (NAND) type memory or flash memory. In an example, a memory component can include one or more memory arrays, and each array includes multiple memory cells such as single-level cells (SLCs) or multiple-level cells (MLCs). Each of the memory cells stores one or more bits of data. In an example, a memory device can include an SLC portion and an MLC portion of memory cells.

In an example, a memory device includes or uses control circuitry. The control circuitry can comprise complementary metal-oxide-semiconductor (“CMOS”) circuitry, or CMOS-based circuitry, that is configured to interface the memory device with a host or other components. The control circuitry can be configured to manage control signal and data signal communication with the cells of the memory array or arrays. In an example, the control circuitry includes a CMOS under array (CUA) configuration.

In an example, a memory device comprises a memory die that is fabricated on a semiconductor substrate, such as silicon. The die can be fabricated on the same substrate as multiple other memory devices and their associated control circuitry, such as comprising other dies. In an example, multiple memory devices and their control circuitry can be fabricated on a single wafer and then a cutting process can be used to separate the individual dies or devices.

In an example, a memory device comprises components that are fabricated on multiple different substrates and then joined or bonded together to provide a final memory device or other intermediate workpiece. For example, a portion of a first wafer can comprise a memory array structure and a portion of a second wafer can comprise the control circuitry. The first and second wafers can be joined, or bonded, and used together to provide a memory device. In an example, the respective portions of the first and second wafers can be diced and the resulting dies can be joined or bonded to provide respective memory devices.

In an example, the control circuitry comprises circuitry that is configured to receive instructions from a host device or system and communicate with an attached memory array, such as to exchange data or commands with one or more of the memory cells of the memory array. The control circuitry can include, for example, integrated circuits, firmware circuits, memory controller circuits, or other circuitry that is configured to provide a translation layer between a host and the memory array. In an example, the control circuitry includes one or more of the row decoder 412, column decoder 414, sense amplifiers 420, page buffer 422, selector 424, input/output (I/O) circuit 426, and/or memory control unit 430 of the memory device 400.

In an example, a process of coupling a first wafer (or first die) comprising a memory array to a second wafer (or second die) containing the control circuitry involves precision alignment and bonding to ensure electrical and mechanical integrity of the final assembly. The wafers or dies can be first subjected to surface preparation, including cleaning and planarization, to create smooth and contaminant-free bonding surfaces. A bonding interface is then established using techniques such as direct bonding, where the wafers or dies are brought into contact, and heat and pressure are applied to facilitate the bond. In some examples, an intermediate layer of a bonding material, such as a fusible alloy or an adhesive polymer, can be used to join the wafers or dies. This intermediate layer can serve dual functions as an electrical interconnect and a mechanical binder. Once aligned and bonded, the wafers or dies form a unified structure and conductive contacts, vias, or other conductive paths are electrically coupled through the bonding interface. This coupling can include metal-to-metal bonding or conductive bumps or pillars that extend from the surfaces of each wafer or die to meet at the interface. The resulting bonded assembly exhibits the structural and electrical characteristics for an integrated inductor to function within the memory device, providing enhanced power management capabilities without compromising the compactness and efficiency of the semiconductor architecture.

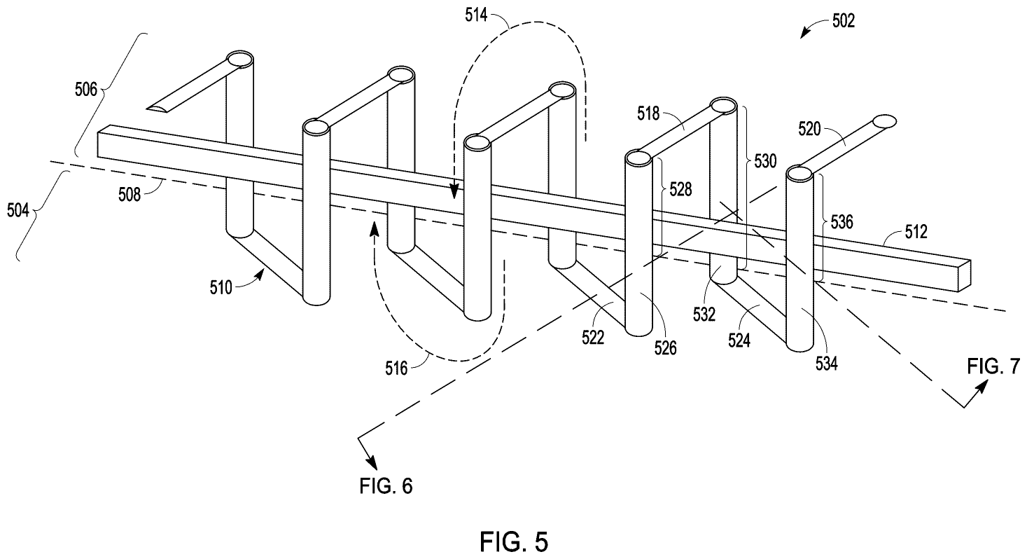

FIG. 5 illustrates generally a simplified diagram of an example inductor 502 that can comprise a bonded assembly of multiple dies or wafers. One or more portions of the example inductor 502 can be provided adjacent to components of an integrated memory device. Such components can include, for example, an array of memory cells or control circuitry for the memory cells, among other things. An array and/or control circuitry are not illustrated in the example of FIG. 5, but it can be understood that such other circuitry can be integrated near or adjacent to one or more portions of the example inductor 502. In some examples, the example inductor 502 can be used for charge storage. For example, a memory device that includes the inductor can include boost converter circuitry that uses the example inductor 502 for charge storage, and can use the stored charge for operation of the memory array.

The example inductor 502 comprises a conductive path 510 that includes second conductive portions 506 and first conductive portions 504 that are joined at a bonding interface 508. The conductive path 510 forms a solenoid around a core 512 region. That is, the conductive path 510 extends along a helical path having a length substantially greater than its width or diameter. When an electric current passes through the conductive path 510, a controlled magnetic field results.

In an example, the second conductive portions 506 each provide less than one revolution of the conductive path 510 of the example inductor 502, and the first conductive portions 504 each provide less than one revolution of the conductive path 510. For example, the second conductive portions 506 can include first turns 514 comprising a top portion of the conductive path 510. In the example of FIG. 5, each of the first turns 514 routes a respective portion of the conductive path 510 around approximately one half of a complete revolution of the example inductor 502. That is, each of the first turns 514 comprises a particular U-shaped segment (downward-facing in the example of FIG. 5) of the conductive path 510. The first conductive portions 504 can include second turns 516 comprising a bottom portion of the conductive path 510. In the example of FIG. 5, each of the second turns 516 routes a respective portion of the conductive path 510 around approximately one half of a complete revolution of the example inductor 502. That is, each of the second turns 516 comprises a particular U-shaped segment (upward-facing in the example of FIG. 5) of the conductive path 510. The various first turns 514 in the top portion of the conductive path 510 can be conductively coupled with corresponding second turns 516 in the bottom portion of the conductive path 510 to provide the continuous conductive path 510 for the example inductor 502.

In an example, the second conductive portions 506 can be provided on a first semiconductor substrate, and the first conductive portions 504 can be provided on a second semiconductor substrate. The first and second semiconductor substrates can comprise the same or different materials. For example, the first semiconductor substrate can comprise a substrate that is shared with control circuitry for one or more memory cells, and the second semiconductor substrate can comprise a substrate that is shared with the one or more memory cells. Notwithstanding any differences in the substrates and/or fabrication techniques used to form the respective conductive portions of the conductive path 510, the second conductive portions 506 and first conductive portions 504 can be joined at the bonding interface 508.

The example inductor 502 includes a core 512. The core 512 can comprise a magnetic or non-magnetic material disposed in or on a respective one of the first and/or second semiconductor substrates. In the example illustrated in FIG. 5, the core 512 comprises a portion of the same semiconductor device that comprises the second conductive portions 506, such as on a first side of the bonding interface 508. In other examples, the core 512 can comprise a portion of the same semiconductor device that comprises the first conductive portions 504, such as on a second side of the bonding interface 508. In other examples, the core 512 can comprise respective portions of each of the semiconductor devices that are joined at the bonding interface 508. The core 512 region can be substantially bound by, or enclosed within, the turns of the helical conductive path 510. In still other examples, the example inductor 502 may not include a designated core region.

In an example, at least one of the second conductive portions 506 and the first conductive portions 504 of the conductive path 510 comprises vias that extend through multiple layers in a portion of a device or die that comprises a memory array. The other of the second conductive portions 506 and the first conductive portions 504 comprises multiple layers in a portion of a device or die that comprises control circuitry for the memory array. Examples of these vias and conductive layers are further described and illustrated herein.

Although the illustrated example of the conductive path 510 shows a structure comprising multiple smooth or contiguous components connected in series, the components of the conductive path 510 can optionally include one or more sub-components that may not be linear or smooth, as shown in other examples herein. Taken together, however, the sub-components that comprise the conductive path 510 can be connected to provide a substantially contiguous helical electrical signal path, to thereby provide the example inductor 502.

In an example, a conductive segment of the conductive path 510 can begin at a first lower connection 522. The first lower connection 522 can be electrically coupled to a first via 526 that extends from the first lower connection 522 to the bonding interface 508. The first lower connection 522 can be electrically coupled to a first conductive path 528 using respective contacts at the bonding interface 508. The first conductive path 528 can extend from the bonding interface 508 to a first side of a first upper connection 518. A second side of the first upper connection 518 can be electrically coupled to a second conductive path 530 that extends to the bonding interface 508. The second conductive path 530 can be electrically coupled to a second via 532 using respective contacts at the bonding interface 508. The second via 532 can be coupled to a first side of a second lower connection 524. A second side of the second lower connection 524 can be coupled to a third via 534, and the third via 534 can be coupled to a third conductive path 536 using respective contacts at the bonding interface 508. The third conductive path 536 can be coupled to a second upper connection 520, and so on. Multiple conductive loops can thus be provided to form a helical signal path that comprises the example inductor 502.

In an example, a first die, such as comprising an array of memory cells, further comprises the first lower connection 522, the first via 526, the second via 532, the second lower connection 524, and the third via 534, among other vias, other lower connections, and corresponding contacts, to provide the first conductive portions 504 of the conductive path 510. The vias can comprise high aspect ratio conductive structures that extend through multiple tiers or layers of a first die, similarly to conductive pillars used in the array of memory cells. The vias can be oriented parallel to one another. In an example, the vias are formed of a conductive material and can include, for example, carbon nanotubes (CNT) that may be partially filled. Other materials can similarly be used. The vias can have various cross-sectional shapes, such as circular, oval, square, rectangular, or hexagonal, among others. According to some examples, each via in the first conductive portions 504 has the same cross-sectional shape. In an example, the lower connections can comprise respective portions of conductive layers (e.g., metal layers) in the first die.

A second die, such as comprising control circuitry for the array of memory cells, further comprises the first conductive path 528, the first upper connection 518, the second conductive path 530, the third conductive path 536, the second upper connection 520, and corresponding contacts, to provide the second conductive portions 506 of the conductive path 510. The conductive paths can each comprise multiple, vertically-connected portions (e.g., islands) of conductive layers in the second die. In other words, a particular conductive path can include at least two vertically spaced apart conductive islands that are electrically coupled in the vertical direction using a conductive contact. The islands can comprise portions of respective metal layers in the second die. The upper connections can comprise respective portions of conductive layers (e.g., metal layers) in the second die. The conductive paths through the second conductive portions 506 can have different characteristics. For example, the respective paths can comprise different numbers of conductive islands, and the conductive islands themselves can have different physical characteristics (e.g., length, width, depth characteristics, etc.).

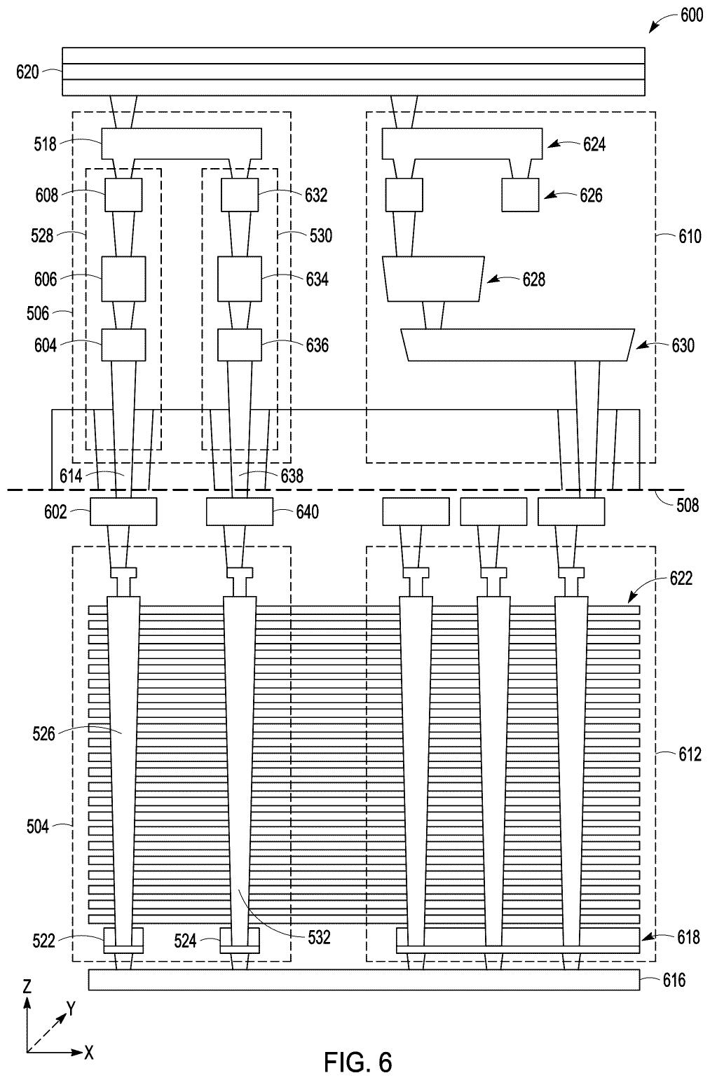

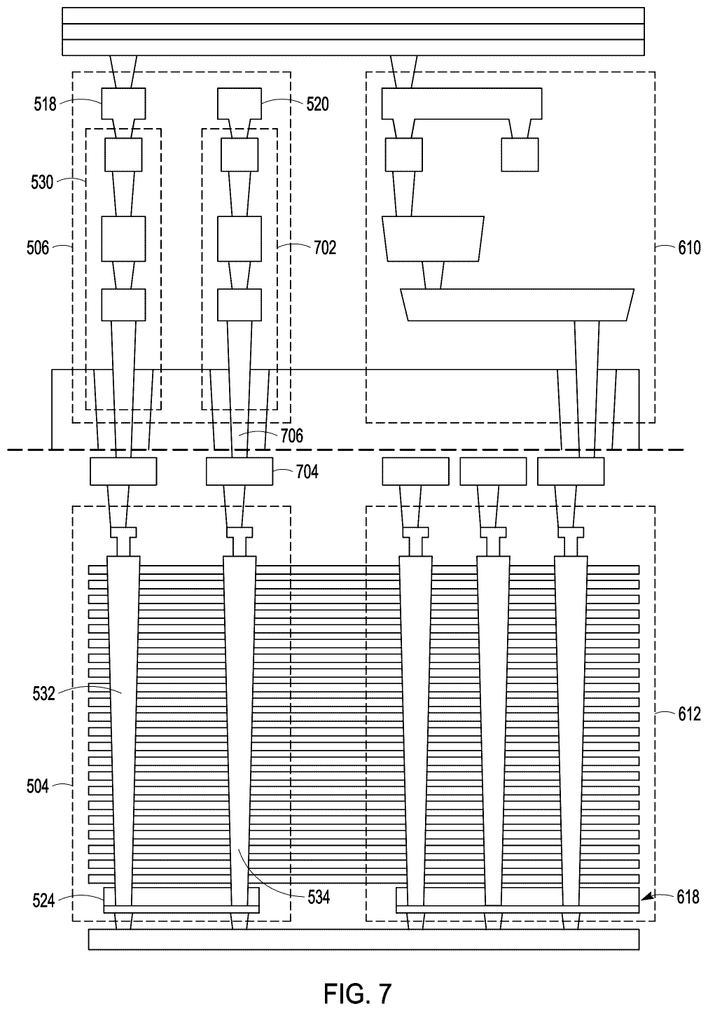

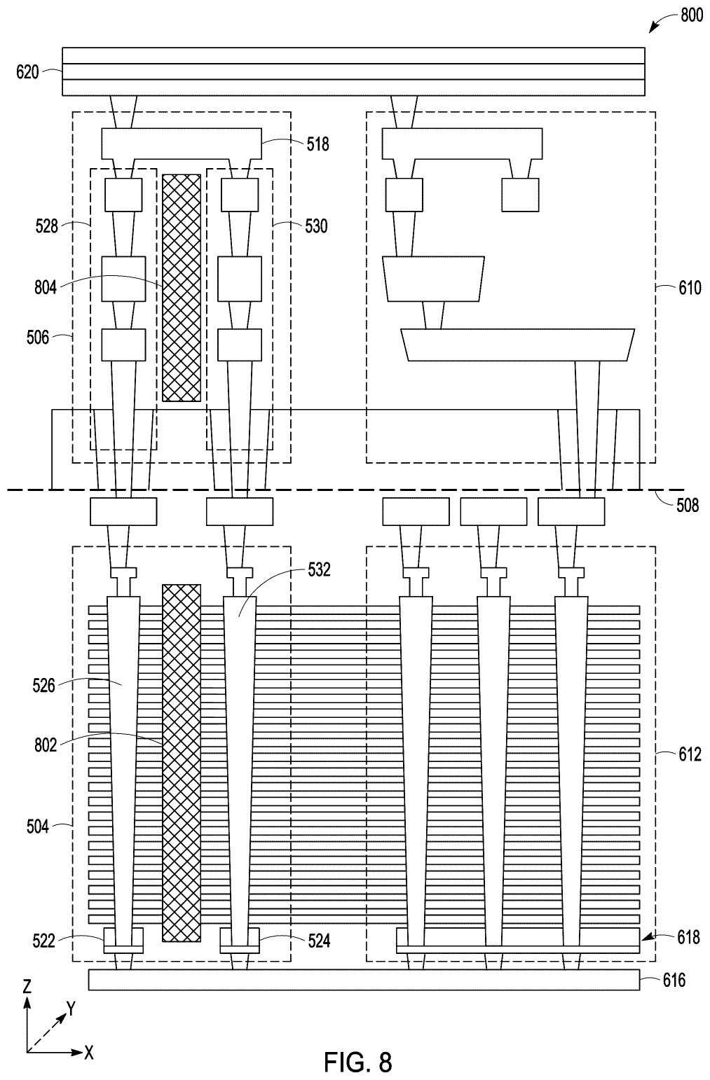

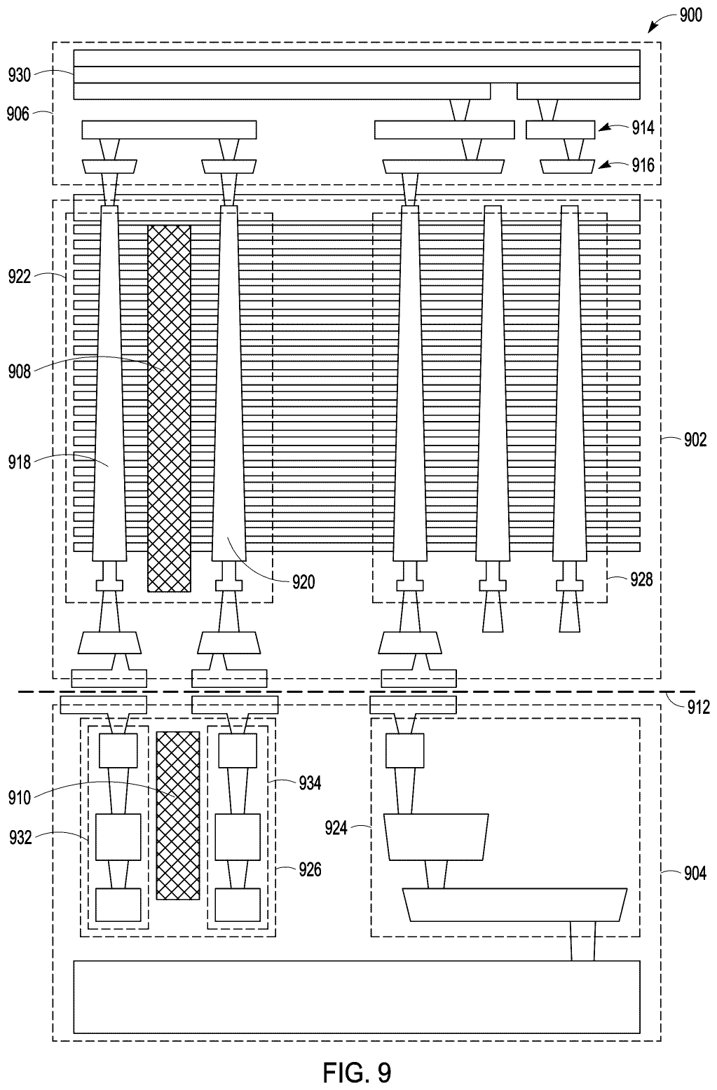

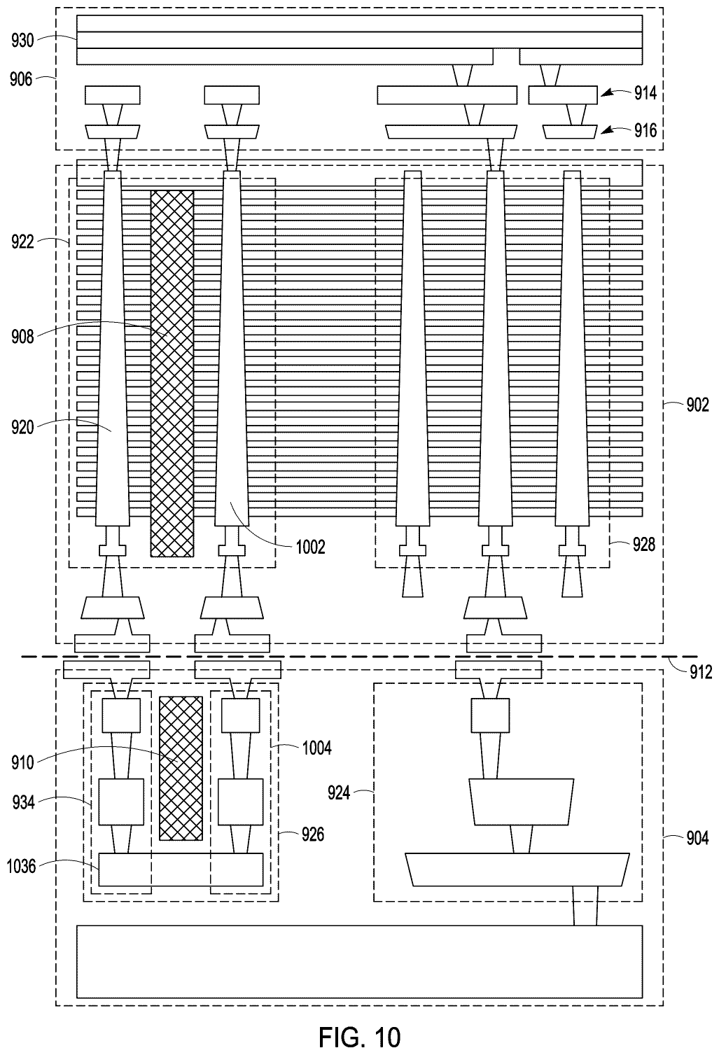

Further examples of the vias, conductive paths, and other layers are provided in the examples of FIG. 6, FIG. 7, FIG. 8, FIG. 9, and FIG. 10.

In an example, fabrication processes used to form an integrated inductor, such as the example inductor 502, can be highly scalable. For example, the each via in the first die can be formed substantially simultaneously, each lower connection in a set of lower connections can be formed substantially simultaneously, and each upper connection in a set of upper connections can be formed substantially simultaneously. That is, the time consumed by inductor fabrication can be mostly independent of a number of turns in the solenoid. Accordingly, the number of turns in the inductor can be increased to increase inductance without impacting fabrication timelines.

FIG. 6 illustrates generally an example of a first portion of a helical conductive path in a portion of a first memory device 600, and the first memory device 600 comprises multiple dies. The first memory device 600 can include the first conductive portions 504 and the second conductive portions 506 that comprise a portion of a conductive path of an inductor, such as the example inductor 502 from the example of FIG. 5.

The first conductive portions 504 can comprise a portion of a first die, and the second conductive portions 506 can comprise a portion of a second die. The first die can comprise various structures formed on a first substrate 616, and the second die can comprise various other structures formed on a second substrate 620. The first and second dies can be coupled or bonded at an interface (e.g., at the bonding interface 508) to provide the first memory device 600. The example of the first memory device 600 in FIG. 6 shows an embodiment with a control circuitry die disposed above or on a memory array die. The example of FIG. 9, discussed below, shows an embodiment of a third memory device 900 that includes a control circuitry die disposed below the memory array die.

The first memory device 600 can comprise a 3D NAND memory device having a 3D memory array. In the illustrated example, the regions of the device are shown in a first vertical cross-section in a z-x plane. The corresponding cross-section is indicated in the example of FIG. 5. The example of the first memory device 600 includes a first die that comprises the first conductive portions 504 of an inductor and a memory array 612. The example of the first memory device 600 further includes a second die that comprises the second conductive portions 506 of the inductor and control circuitry 610 for the memory array 612. The first and second dies are joined at the bonding interface 508 using respective contacts on the dies. For example, pillars coupled to cells of the memory array 612 are electrically coupled to the control circuitry 610 using respective contacts on the first die and the second die.

The memory array 612 includes memory cells arranged in horizontal planes (e.g., x-y planes) that are disposed vertically under the control circuitry 610 and the bonding interface 508. The memory cells are structured as multiple arranged tiers 622 comprising various memory cells. The tiers 622 can include, for example, multiple oxide and nitride layers.

In an example, the first die comprises a portion of a memory array wafer, such as can be used in a NAND memory device. For ease of illustration, fewer than all elements of an array are shown. Memory cells of the tiers 622 can extend from pillars in the second die. Three such pillars are shown in the example of FIG. 6, however, other pillars can be located with respect to the tiers 622.

The first die can include various conductive contact vias that can comprise portions of a conductive path of an inductor in the first memory device 600. For example, the first die can include conductive contact vias, such as the first via 526 and the second via 532. In an example, the pillars, the conductive contact vias, and conductive contacts or plugs, can extend above and below the tiers 622 and can contact different metallization levels, which can be at various vertical locations in the structure of the 3D array, such that access to the memory cells in the tiers 622, or access to the first conductive portions 504 of an inductor, can be provided to an external device. The pillars, vias, and contacts, among other similar structures, can provide vertical connections extending from a bottom metal layer 618, though the 3D memory array, or through regions adjacent to the array, which in turn can be used to couple to sensing circuitry and other control logic of the control circuitry 610 for the memory array.

In an example, a top portion of the memory array 612, or a top portion of the first conductive portions 504, can be covered in part by a passivation layer. The passivation layer is an electrically insulating layer and can include one or more materials such as, but not limited to, tetraethyl orthosilicate (TEOS) and an oxynitride. The oxynitride, for example, can include silicon oxynitride. One or more metal layers or islands can be provided as contacts in or through the passivation layer and can be configured to interface with contacts from the second die at the bonding interface 508.

In the example of FIG. 6, the first conductive portions 504 of the memory device inductor are coupled to respective second conductive portions 506. The first conductive portions 504 can include a first via 526 that extends in the first die from the first lower connection 522 (e.g., comprising a portion of a bottom metal layer 618), through the tiers 622 of the first die, to a first interface contact 602 at a first side of the bonding interface 508. One or more other intervening contacts or layers may be provided such that a substantially vertical conductive path is established through a portion of the first die. The first interface contact 602 can be electrically coupled to a second interface contact 614 in the second die.

The second conductive portions 506 can include a conductive path that extends from the second interface contact 614. For example, the second conductive portions 506 can include a conductive path that includes the second interface contact 614, a first metal island 604, a second metal island 606, a third metal island 608, and a first upper connection 518. The upper connection and the various metal islands can correspond to respective different metal layers in the second die. For example, the first upper connection 518 can comprise a portion of a first metal layer 624, the third metal island 608 can comprise a portion of a second metal layer 626, the second metal island 606 can comprise a portion of a third metal layer 628, and the first metal island 604 can comprise a portion of a fourth metal layer 630. The upper connection and the various metal islands can be electrically coupled in series, using respective inter-layer contacts, to provide a continuous electrical signal path that extends vertically in the second die from the second interface contact 614 to the first upper connection 518. Fewer or additional islands and inter-layer contacts can similarly be used.

In the example of FIG. 6, the first upper connection 518 electrically couples the third metal island 608 to a fourth metal island 632. The third metal island 608 and the fourth metal island 632 can comprise respective portions of the second metal layer 626. That is, the third metal island 608 and the fourth metal island 632 can be electrically isolated in the plane of the second metal layer 626, but can be coupled using conductors in one or more other layers, such as using the first upper connection 518 of the first metal layer 624.

In an example, the second conductive portions 506 include a signal path that extends down from the fourth metal island 632, through a fifth metal island 634 of the third metal layer 628, through a sixth metal island 636 of the fourth metal layer 630, and terminates at a third interface contact 638 at the bonding interface 508. The signal path can extend across the bonding interface 508 using a fourth interface contact 640 that is coupled to the third interface contact 638, and further to the second via 532 and the second lower connection 524 at the bottom metal layer 618. The conductive path that extends from the first lower connection 522 to the second lower connection 524 comprises approximately three-quarters of a complete loop, such as can comprise a portion of a helical conductive path of an inductor, such as the example inductor 502.

The second die can comprise a portion of a CMOS wafer. In an example, the second substrate 620 of the second die comprises a polyimide substrate, and the control circuitry 610 is formed using multiple layers on the substrate. In an example, the control circuitry 610 can be implemented with one or more circuits structured in a n-well ring for resistive ground domain segregation. In an example, the control circuitry 610 portion of the second die can include pads to couple to nodes for external connections or pins of the package for the first memory device 600.

The non-limiting example of FIG. 6 includes multiple metal layers at various depths (or heights, depending on the perspective) in the second die. For example, the second die can include the first metal layer 624 disposed at or adjacent to the second substrate 620. The second die can further include one or more other layers, such as the second metal layer 626, the third metal layer 628, and the fourth metal layer 630. Additional, fewer, or other metal layers can optionally be used. The metal layers can comprise, or can provide electrical coupling with, circuit elements in the control circuitry 610. In some examples, metal layers may be replaced with conductively doped semiconductor material, such as but not limited to conductively doped polysilicon. Electrical connections between metal layers or conductive semiconductor layers at different vertical levels in the second die can be provided by conductive contact vias that extend between the various levels in the z-direction.

In the example of FIG. 6, the first and second dies comprise portions of respective different wafers that are bonded together at the bonding interface 508. In some examples, bonding can be performed at the wafer level, where the wafers are bonded before being segmented into dies. In other examples, bonding can be performed at the die level, after the wafers have been divided into individual dies.

In an example, a bonding procedure includes connecting two integrated circuit (IC) structures, which could be manufactured by different producers, such as using varied materials or different fabrication techniques. A “bottom face” or “back side” of an IC structure denotes its underside, while the “top face” or “front side” indicates the opposite side.

The orientation of the bonded IC structures can generally be defined in three configurations: face-to-face (f2f), face-to-back (f2b), and back-to-back (b2b). In an f2f configuration, the front side of one IC structure is bonded to the front side of another. In an f2b configuration, the front side of one IC structure is bonded to the backside of another, or the reverse. In a b2b configuration, the backside of one IC structure is bonded to the backside of another. In the examples discussed herein, the memory array 612 (or other memory array die or wafer), or the control circuitry 610 (or other control circuitry die or wafer), or respective portions of a conductive path of an inductor, can be configured for any of f2f, f2b, or b2b bonding.

Bonding may be achieved through insulator-insulator bonding, such as oxide-oxide bonding, where insulating layers of the IC structures are joined. A bonding material may be used between the faces of the IC structures to be bonded. This material can serve as an adhesive, an etch-stop, or both, and is applied to the bonding surfaces before the structures are pressed together and heated to a suitable temperature, typically between 50 and 200 degrees Celsius.

Other bonding techniques can similarly be used. For example, metal diffusion bonding or eutectic bonding, among other techniques, can be used. In metal diffusion bonding, metals such as gold, copper, or aluminum can be used as an intermediate layer to facilitate the bonding process. The metal layers diffuse into each other to form a solid bond at the bonding interface 508. In eutectic bonding, a combination of materials can be used to form a eutectic system, melting at a lower temperature than their individual melting points. This allows for bonding at temperatures lower than the melting point of the base wafers, preventing damage to the IC structures.

Surface preparation is critical for successful bonding, as it ensures clean and flat bonding surfaces. Surface preparation may involve chemical cleaning, plasma cleaning, and surface planarization techniques. Environmental control is also crucial during the bonding process. Factors such as temperature, pressure, and ambient atmosphere must be carefully controlled to achieve a high-quality bond. In some examples, wafers can be bonded together without an additional material, creating a bonding interface that can be identified as a seam or thin layer. The choice of bonding technique depends on the materials involved, the desired electrical and mechanical properties of the bond, and the intended application of the bonded wafers.

As described above, the example of FIG. 6 shows a first portion of a helical conductive path of an inductor in the first memory device 600. FIG. 7 illustrates generally a second portion of the helical conductive path in another portion of the first memory device 600. The first and second portions of the helical conductive path can be electrically coupled to provide more than one full turn of the conductive path.

In the illustrated example of FIG. 7, the regions of the memory device are shown in a vertical cross-section that is rotated about the z-axis from the example illustrated in FIG. 6. The corresponding cross-section is indicated in the example of FIG. 5. Taken together, the illustrated examples of FIG. 6 and FIG. 7 show different vertical cross-section views of different portions of the helical conductive path of the same inductor (e.g., the example inductor 502).

The example of FIG. 7 includes the second conductive path 530 that extends from the first upper connection 518 in the second die to the second via 532 in the first die. In the first die, the second via 532 is coupled to the third via 534 using the second lower connection 524. The second lower connection 524 comprises a portion of the bottom metal layer 618 of the first die.

In an example, the second lower connection 524 is a member of a set of lower connections in the first die. The set of lower connections can be formed during various processes of fabricating a memory device, according to some examples. According to some examples, the set of lower connections are metal layers, such as comprising tungsten, and the layers occupy the same or different planes in a circuitry-under-array (CuA) or circuitry-over-array (CoA) region of the first die. The set of lower connections can be formed by a fabrication process used to form the other metal layers in die. For example, a hard mask can be applied and selectively etched to form holes in the desired shapes of the lower connections. A metal (or other conductive material) is deposited to fill the holes in the mask. The mask is etched away, leaving the set of lower connections. According to some examples, the set of lower connections are formed after formation of structures of a CoA region. One or more of the upper connections and lower connections can comprise a terminus or tap for the integrated inductor.

The conductive path of the inductor can extend from the third via 534 to a third conductive path 702 in the second die. For example, the third via 534 can be coupled to a fifth interface contact 704 of the first die, and the fifth interface contact 704 can be coupled to a sixth interface contact 706 of the second die at the bonding interface 508. The sixth interface contact 706 can be coupled to a second upper connection 520 (e.g., comprising a portion of the first metal layer 624 in the second die) using the various metal layers of the second die that comprise the third conductive path 702. The second upper connection 520 can be coupled to a further conductive path portion of the inductor in the second die (not illustrated in the example of FIG. 7).

FIG. 8 illustrates generally an example of a first portion of a helical conductive path in a portion of a second memory device 800. The example of the second memory device 800 can include an instance of some or all of the components of the first memory device 600 from the example of FIG. 6, as indicated by use of the same reference numbers to refer to device components that can be the same in the first memory device 600 and the second memory device 800. For example, the second memory device 800 can similarly include the first conductive portions 504 of a first die coupled to the second conductive portions 506 of a second die at the bonding interface 508 to provide a portion of the helical conductive path of an inductor (e.g., the example inductor 502).

The example of the second memory device 800 includes a portion of the inductor with a core (see, e.g., the core 512 from the example of FIG. 5). The core can comprise a region of one or both of the first and second dies that comprise the second memory device 800. The conductive path of the inductor can include multiple turns or windings around the core.

In an example, the first die can comprise a first core 802. The first core 802 can be bound by, and electrically insulated from, the first via 526 and the second via 532. That is, the first core 802 can occupy a portion of the first die that is electrically separate from the vias and/or other conductive layers or contacts that comprise the first conductive portions 504 of the inductor.

The second die can comprise a second core 804. The second core 804 can be bound by, and electrically insulated from, the first conductive path 528, the first upper connection 518, and the second conductive path 530. That is, the second core 804 can occupy a portion of the second die that is electrically separate from the conductive islands and/or layer portions that comprise the second conductive portions 506 of the inductor.

In the example of FIG. 8, the first core 802 and the second core 804 are each spaced apart from the bonding interface 508 by one or more layers. In other examples, one or both of the first core 802 and the second core 804 can extend to the bonding interface 508. In an example, the first core 802 and the second core 804 can be coupled at the bonding interface 508 to provide a substantially contiguous core structure for the integrated inductor. The first core 802 or the second core 804 can be formed in their respective dies using various fabrication techniques, such as a deep etch to form a trench. The trench can optionally be filled with a magnetic or non-magnetic material, or can comprise an air core. Length, width, depth, and fill material characteristics of the core region(s) can be adjusted to change inductance characteristics of the inductor.

In an example, the core region(s) can be filled with a block of oxide during formation or layering. The oxide can be etched to form an oblong trench or hole between the conductive path portions. Sputtering can be used to achieve a precise shape of the oblong hole. According to some examples, the oblong hole is of a height (z-direction) greater than that of the resultant core region. The oblong hole can be at least partially filled with a ferromagnetic material to form a magnetic core. According to some examples, the ferromagnetic material is deposited via CVD or PVD. In other examples, the hole can be filled with a non-ferromagnetic material or can be an air core.

FIG. 9 illustrates generally an example of a first portion of a helical conductive path of an inductor in a portion of a third memory device 900, and the third memory device 900 comprises multiple dies. The example of FIG. 9 shows an embodiment that includes a control circuitry die 904 disposed below a memory array die 902. The control circuitry die 904 can be coupled to the memory array die 902 at a bonding interface 912.

In an example, the control circuitry die 904 comprises a control circuitry portion 924 and a conductive path portion 926. The control circuitry portion 924 can comprise control circuitry or logic configured to control operation of memory cells in the memory array die 902. The conductive path portion 926 can comprise multiple conductive paths that correspond to respective turns or segments of a helical conductive path of the inductor in the third memory device 900. In an example, the inductor in the third memory device 900 comprises an embodiment of the example inductor 502.

In an example, the conductive path portion 926 can include a first conductive path 932 and a second conductive path 934, and each of the conductive paths can extend vertically through a portion of the control circuitry die 904. In the cross-section of the third memory device 900 illustrated in FIG. 9, the first conductive path 932 can be electrically isolated from the second conductive path 934 within the illustrated portion of the control circuitry die 904. In an example, the first conductive path 932 comprises multiple conductive islands on respective different layers of the control circuitry die 904. Islands on adjacent layers can be coupled using respective contacts. The second conductive path 934 can be similarly configured using other conductive islands on the same or different layers of the control circuitry die 904.

The memory array die 902 comprises a cell array portion 928 and conductive via portion 922. The cell array portion 928 can comprise stacked memory cells. The cell array portion 928 can be electrically coupled to the control circuitry portion 924 of the control circuitry die 904 using respective contacts at the bonding interface 912. The conductive via portion 922 can comprise multiple conductive paths that correspond to respective segments of a helical conductive path of the inductor in the third memory device 900.

In the example of FIG. 9, the memory array die 902 includes a first core 908 and the control circuitry die 904 includes a second core 910. The cores can comprise respective doped, filled, or other regions in the third memory device 900 that are bound by the helical conductive path of the inductor. Other examples can include a core in one of the memory array die 902 and the control circuitry die 904, and still other examples can omit a core region.

The third memory device 900 includes one or more finishing layers 906 coupled to a back side of the memory array die 902. The finishing layers 906 comprise various metallization layers and pads. In an example, one or more back side layers of the memory array die 902 can be removed during device processing, and the finishing layers 906 can be formed on the processed back side of the memory array die 902.

In an example, the finishing layers 906 include a first metal layer 914 and a second metal layer 916, such as can be formed on a polyimide substrate 930. In the vertical cross-section of the third memory device 900 shown in FIG. 9, the first metal layer 914 electrically couples signal path segments that include the first via 918 and the second via 920. For example, the first via 918 can be coupled to a first conductive island in a second metal layer 916, and the first conductive island can be coupled to the first metal layer 914. Similarly, the second via 920 can be coupled to a second conductive island in the second metal layer 916, and the second conductive island can be coupled to the first metal layer 914. Accordingly, a first turn of the helical conductive path can be provided from the first via 918, through a portion of the first metal layer 914, and to the second via 920. Other segments and turns can be provided similarly to the other memory device examples discussed herein, such as using upper or lower connections in the control circuitry die 904, the memory array die 902, and/or the finishing layers 906.

As described above, the example of FIG. 9 shows a first portion of a helical conductive path of an inductor in the third memory device 900. FIG. 10 illustrates generally a second portion of the helical conductive path in another portion of the third memory device 900. The first and second portions of the helical conductive path can be electrically coupled to provide more than one full turn of the conductive path.

In the illustrated example of FIG. 10, the regions of the memory device are shown in a vertical cross-section that is rotated about the z-axis from the example illustrated in FIG. 9. Taken together, the illustrated examples of FIG. 9 and FIG. 10 show different vertical cross-section views of different portions of the helical conductive path of the same inductor.

In the example of FIG. 10, the conductive via portion 922 of the memory array die 902 comprises the second via 920 and a third via 1002. The vias can be coupled to one or more metal layers in the finishing layers 906. For example, the second via 920 can be coupled to conductive islands in the second metal layer 916 and the first metal layer 914. Similarly, the third via 1002 can be coupled to other conductive islands in the second metal layer 916 and the first metal layer 914. The metal islands that comprise the first metal layer 914 can be electrically decoupled in the illustrated cross-sectional portion of the finishing layers 906 of FIG. 10, whereas the metal islands that comprise the first metal layer 914 can be electrically coupled in the cross-sectional portion of the finishing layers 906 in FIG. 9.

In the example of FIG. 10, the conductive path portion 926 of the control circuitry die 904 comprises the second conductive path 934 and a third conductive path 1004. The conductive paths can comprise conductive islands on multiple, vertically spaced-apart layers of the control circuitry die 904. In an example, the second conductive path 934 can be electrically coupled to the third conductive path 1004 using a lower connection 1036 that comprises a portion of a metal layer of the control circuitry die 904.

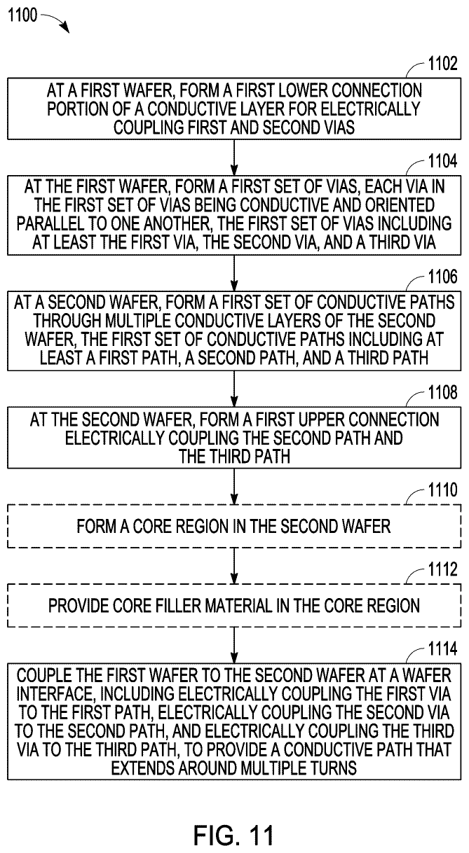

FIG. 11 illustrates generally an example of an inductor formation method 1100, such as can be used to form an integrated inductor for a memory device. In an example, operations of the inductor formation method 1100 can be used to provide the example inductor 502 using multiple dies or wafers.

At operation 1102, the inductor formation method 1100 can include, at a first wafer, forming a first lower connection portion of a conductive layer that will electrically couple first and second vias. In an example, the first lower connection comprises a portion of a metal layer (e.g., a bottom metal layer) in the first wafer. The first wafer can include a memory array, such as comprising memory cells for a NAND memory device.

At operation 1104, the inductor formation method 1100 includes, at the first wafer, forming a first set of vias. Each via in the first set of vias can include a conductive structure, and each via can be oriented substantially parallel to the others of the first set of vias. In an example, the vias can be formed at operation 1104 concurrently with formation of one or more other vias or pillars that comprise cells of a memory array on the first wafer. For example, the vias can be formed through a stack of interleaved oxide and nitride layers of the first wafer. In an example, the first set of vias formed at operation 1104 includes at least the first via, the second via, and a third via. The first and second vias can be electrically coupled to the first lower connection formed at operation 1102.

At operation 1106, the inductor formation method 1100 can include, at a second wafer, forming a first set of conductive paths through multiple conductive layers of the second wafer. In an example, the second wafer comprises a CMOS wafer and includes control circuitry for operation of the memory cells of the memory array on the first wafer. For example, the control circuitry can include one or more of the row decoder 412, column decoder 414, sense amplifiers 420, page buffer 422, selector 424, input/output (I/O) circuit 426, and/or memory control unit 430 of the memory device 400 from the example of FIG. 4. The first set of conductive paths formed at operation 1106 can include at least a first path, a second path, and a third path. The paths can be separate conductive paths or regions that can be joined in series by one or more other features, layers, contacts, or other components (e.g., on one or more other wafers) to provide a continuous signal path. In an example, each of the conductive paths comprises multiple conductive islands in two or more layers of the second wafer, and the islands are electrically coupled using vertical contacts between the layers.

At operation 1108, the inductor formation method 1100 can include, at the second wafer, forming a first upper connection electrically coupling the second path and the third path. In an example, the first upper connection comprises a portion of a metal layer (e.g., a bottom metal layer or top metal layer, depending on the orientation of the second wafer) in the second wafer that comprises the control circuitry.

At operation 1110, the inductor formation method 1100 can optionally include forming a core region in the second wafer. For example, operation 1110 can include etching or forming a trench in a portion of the second wafer that is physically located between the first, second, and third paths of the first set of conductive paths in the second wafer. In other words, the conductive paths can bound, at least in part, lateral side edges or faces of the core region that is formed in the second wafer. At operation 1112, the inductor formation method 1100 can optionally include providing a core filler material in the core region. For example, operation 1112 can include sputtering or depositing a magnetic or non-magnetic material in the core region. In an example, operation 1110 includes forming the core region at or near a surface of the second wafer such that the core region is at or adjacent to a wafer interface.

At operation 1114, the inductor formation method 1100 includes coupling the first wafer to the second wafer at the wafer interface. The operation 1114 can include electrically coupling the first via to the first path, electrically coupling the second via to the second path, and electrically coupling the third via to the third path to provide a conductive path that extends around multiple turns and forms a solenoid-shaped conductive path to thereby form an inductor.

To illustrate some of the inductor structures and formation or fabrication techniques described herein, a non-limiting set of Example embodiments are set forth below as numerically identified Examples.
Example 1 is a memory device comprising: an array of memory cells provided on a first semiconductor substrate; first conductive portions of an inductor provided on the first semiconductor substrate, wherein each of the first conductive portions provides less than one revolution of a conductive path of the inductor; and second conductive portions of the inductor, wherein the second conductive portions are vertically separate from the first conductive portions and coupled to the first conductive portions to provide multiple revolutions of the conductive path of the inductor.
In Example 2, the subject matter of Example 1 optionally includes the second conductive portions of the inductor are provided on a separate second semiconductor substrate.
In Example 3, the subject matter of any one or more of Examples 1-2 optionally includes the first conductive portions of the first inductor are provided adjacent to the array of memory cells.
In Example 4, the subject matter of Example 3 optionally includes the second conductive portions of the first inductor are provided adjacent to control circuitry configured to operate the array of memory cells.
In Example 5, the subject matter of Example 4 optionally includes the second conductive portions of the first inductor and the control circuitry comprise portions of a CMOS die.
In Example 6, the subject matter of Example 5 optionally includes the CMOS die comprising multiple metal and dielectric layers, and wherein the second conductive portions extend through multiple layers of the CMOS die.
In Example 7, the subject matter of any one or more of Examples 1-6 optionally includes a core of the first inductor.
In Example 8, the subject matter of Example 7 optionally includes the second conductive portions of the inductor are provided on a separate second semiconductor substrate, and the core comprises first and second portions provided on the first and second semiconductor substrates, respectively.
In Example 9, the subject matter of any one or more of Examples 7-8 optionally includes the core comprising a magnetic material or a non-magnetic material disposed therein.
Example 10 is an apparatus comprising: a first semiconductor die including: a first group of pillars extending vertically from a first substrate, each of the pillars of the first group of pillars corresponding to multiple tiers of memory cells; and a first group of vias extending vertically from the first substrate, each of the vias corresponding to portions of a conductive path that comprises an inductor; and a second semiconductor die including: control circuitry configured to control operation of the memory cells; and conductive layers comprising layered portions of the conductive path that comprises the inductor; wherein the first and second semiconductor dies are coupled at a die interface, wherein each revolution of multiple revolutions of the conductive path extends partially through the first and second semiconductor dies.
In Example 11, the subject matter of Example 10 optionally includes the second semiconductor die comprising a CMOS die.
In Example 12, the subject matter of Example 11 optionally includes the first group of pillars is horizontally adjacent to the first group of vias in the first semiconductor die, and the layered portions of the conductive path are horizontally adjacent to at least a portion of the control circuitry in the second semiconductor die.
In Example 13, the subject matter of any one or more of Examples 10-12 optionally includes a first core of the inductor, wherein the first core is disposed in a trench formed in the first semiconductor die.
In Example 14, the subject matter of Example 13 optionally includes a second core of the inductor, wherein the second core is disposed in a trench formed in the second semiconductor die.
In Example 15, the subject matter of any one or more of Examples 10-14 optionally includes a core of the inductor, wherein at least a portion of the core is disposed in a trench formed in one or both of the first semiconductor die and the second semiconductor die.
In Example 16, the subject matter of Example 15 optionally includes the trench comprising a magnetic material or a non-magnetic material disposed therein.
In Example 17, the subject matter of any one or more of Examples 10-16 optionally includes the conductive layers comprising a first layered portion of the conductive path that extends vertically along a first side of the inductor, the first layered portion including: a first conductive island in a first layer that is parallel to a second substrate of the second semiconductor die; a second conductive island in a second layer that is parallel to the second substrate; and a conductive contact coupling the first and second conductive islands, the conductive contact extending orthogonally to the first and second conductive islands.
In Example 18, the subject matter of Example 17 optionally includes the conductive layers comprising a second layered portion of the conductive path that extends vertically along a second side of the inductor.
In Example 19, the subject matter of Example 18 optionally includes the conductive layers comprise a connecting layer that extends from the first side to the second side of the inductor, the connecting layer electrically coupled to the first and second layered portions to provide a first turn of the conductive path.
In Example 20, the subject matter of any one or more of Examples 10-19 optionally includes each revolution of multiple revolutions of the conductive path includes a first turn comprising a conductive layer of the first semiconductor die and a second turn comprising a conductive layer of the second semiconductor die.
Example 21 is an apparatus comprising means to implement of any of any one or more of Examples 1-20.
Example 22 is a method to implement or fabricate all or a portion of any of any one or more of the devices, structures, or other components of Examples 1-20.

Each of these non-limiting examples can stand on its own or can be combined in various permutations or combinations with one or more of the other examples.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” can include “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skill in the art upon reviewing the above description. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A memory device comprising:
an array of memory cells provided on a first semiconductor substrate;
first conductive portions of an inductor provided on the first semiconductor substrate, wherein each of the first conductive portions provides less than one revolution of a conductive path of the inductor; and
second conductive portions of the inductor, wherein the second conductive portions are vertically separate from the first conductive portions and coupled to the first conductive portions to provide multiple revolutions of the conductive path of the inductor.

2. The memory device of claim 1, wherein the second conductive portions of the inductor are provided on a separate second semiconductor substrate.

3. The memory device of claim 1, wherein the first conductive portions of the first inductor are provided adjacent to the array of memory cells.

4. The memory device of claim 3, wherein the second conductive portions of the first inductor are provided adjacent to control circuitry configured to operate the array of memory cells.

5. The memory device of claim 4, wherein the second conductive portions of the first inductor and the control circuitry comprise portions of a CMOS die.

6. The memory device of claim 5, wherein the CMOS die comprises multiple metal and dielectric layers, and wherein the second conductive portions extend through multiple layers of the CMOS die.

7. The memory device of claim 1, comprising a core of the first inductor.

8. The memory device of claim 7, wherein the second conductive portions of the inductor are provided on a separate second semiconductor substrate, and wherein the core comprises first and second portions provided on the first and second semiconductor substrates, respectively.

9. The memory device of claim 7, wherein the core comprises a magnetic material or a non-magnetic material disposed therein.

10. An apparatus comprising:
a first semiconductor die including:
a first group of pillars extending vertically from a first substrate, each of the pillars of the first group of pillars corresponding to multiple tiers of memory cells; and
a first group of vias extending vertically from the first substrate, each of the vias corresponding to portions of a conductive path that comprises an inductor; and
a second semiconductor die including:
control circuitry configured to control operation of the memory cells; and
conductive layers comprising layered portions of the conductive path that comprises the inductor;
wherein the first and second semiconductor dies are coupled at a die interface, wherein each revolution of multiple revolutions of the conductive path extends partially through the first and second semiconductor dies.

11. The apparatus of claim 10, wherein the second semiconductor die comprises a CMOS die.

12. The apparatus of claim 11, wherein the first group of pillars is horizontally adjacent to the first group of vias in the first semiconductor die, and wherein the layered portions of the conductive path are horizontally adjacent to at least a portion of the control circuitry in the second semiconductor die.

13. The apparatus of claim 10, comprising a first core of the inductor, wherein the first core is disposed in a trench formed in the first semiconductor die.

14. The apparatus of claim 13, comprising a second core of the inductor, wherein the second core is disposed in a trench formed in the second semiconductor die.

15. The apparatus of claim 10, comprising a core of the inductor, wherein at least a portion of the core is disposed in a trench formed in one or both of the first semiconductor die and the second semiconductor die.

16. The apparatus of claim 15, wherein the trench comprises a magnetic material or a non-magnetic material disposed therein.

17. The apparatus of claim 10, wherein the conductive layers comprise a first layered portion of the conductive path that extends vertically along a first side of the inductor, the first layered portion including:
a first conductive island in a first layer that is parallel to a second substrate of the second semiconductor die;
a second conductive island in a second layer that is parallel to the second substrate; and
a conductive contact coupling the first and second conductive islands, the conductive contact extending orthogonally to the first and second conductive islands.

18. The apparatus of claim 17, wherein the conductive layers comprise a second layered portion of the conductive path that extends vertically along a second side of the inductor.

19. The apparatus of claim 18, wherein the conductive layers comprise a connecting layer that extends from the first side to the second side of the inductor, the connecting layer electrically coupled to the first and second layered portions to provide a first turn of the conductive path.

20. The apparatus of claim 10, wherein each revolution of multiple revolutions of the conductive path includes a first turn comprising a conductive layer of the first semiconductor die and a second turn comprising a conductive layer of the second semiconductor die.
